(19) United States
(12) Patent Application Publication
(10) Pub. No.: US 2011/0085286 A1
(43) Pub. Date: Apr. 14, 2011

(54) ELECTRONIC APPARATUS

(75) Inventors: Kaigo TANAKA, Kawasaki (JP); Yoshiyuki Sando, Kawasaki (JP)

(73) Assignee: Fujitsu Limited, Kawasaki (JP)

(21) Appl. No.: 12/899,639

(22) Filed: Oct. 7, 2010

(30) Foreign Application Priority Data
Oct. 8, 2009 (JP) 2009-234433

(51) Int. Cl. H05K 7/00; H05K 7/20

(52) U.S. Cl. 361/679.01; 174/559; 174/547

(57) ABSTRACT

An electronic apparatus includes a substrate that includes a component, a first cover member that includes a first position control section for controlling a position of the substrate, and a second cover member that forms an internal space in cooperation with the first cover member and includes a second position control section for controlling the position of the substrate relatively more precisely than the first position control section, wherein when the substrate is supported by either one of the first cover member and the second cover member, the substrate is not fixed to the one of the cover members, and when the first cover member and the second cover member are fastened together, the substrate is fixed in the internal space.

### CROSS-REFERENCE TO RELATED APPLICATIONS

This application is based upon and claims the benefit of priority from the prior Japanese Patent Application No. 2009-234433 filed on Oct. 8, 2009, the entire contents of which are incorporated herein by reference.

### FIELD

Various embodiments discussed herein relate to an electronic apparatus including a substrate on which components are mounted.

### BACKGROUND

An electronic apparatus having a structure in which a housing having an inner space is formed by two cover members and a substrate on which components are mounted is contained in the inner space is widely known. The two covers are, for example, a bottom cover having a dish-shape that opens upward and a top cover that is placed on the bottom cover and forms the inner space with the bottom cover. In an assembling operation of an electronic apparatus having such a structure, a process in which a substrate is fixed inside the bottom cover by screws or the like, the top cover is placed on the bottom cover, and then the top cover and the bottom cover are fixed with screws is widely employed. As a screw fixing structure of the top cover and the bottom cover, from the viewpoint of design, in many cases, a structure is employed in which the bottom cover and the top cover are fixed with screws from the bottom cover so that the screw heads do not appear on the top cover. A component replacement procedure when a component fails in an electronic apparatus having the above structure is as follows. First, an operator puts the electronic apparatus upside down so that the bottom cover is placed over the top cover, and removes the screws fixing the bottom cover and the top cover. Next, the operator puts the electronic apparatus upside down again so that the bottom cover is placed under the top cover, removes the top cover, and removes the screws fixing the substrate to the electronic apparatus if necessary. When the component to be replaced is mounted on a surface of the substrate facing the bottom cover, the operator further takes out the substrate from the bottom cover, puts the substrate upside down, and removes the component to be replaced from the substrate.

When replacing a component of an electronic apparatus having such a structure, the component replacement operation by an operator is cumbersome. In many cases, the substrate is not present separately in the housing, but connected to various other components via connectors or the like. This makes the component replacement operation more cumbersome.

Japanese Unexamined Patent Application Publication No. 2002-246767 discloses a structure in which a circuit board contained in a case which is divided into an upper case and a lower case is tightened together with the upper case and the lower case and position control of the circuit board is performed by only one of the cases.

Japanese Unexamined Patent Application Publication No. 2008-4659 discloses a specific structure which does not cause a position gap or a drop out even when an open/close button is placed upside down during an assembly operation.

### SUMMARY

An electronic apparatus includes a substrate that includes a component; a first cover member that includes a first position control section for controlling a position of the substrate; and a second cover member that forms an internal space in cooperation with the first cover member and includes a second position control section for controlling the position of the substrate relatively more precisely than the first position control section, wherein when the substrate is supported by either one of the first cover member and the second cover member, the substrate is not fixed to the one of the cover members, and when the first cover member and the second cover member are fastened together, the substrate is fixed in the internal space.

The object and advantages of the various embodiments will be realized and attained by means of the elements and combinations particularly pointed out in the claims. It is to be understood that both the foregoing general description and the following detailed description are exemplary and explanatory and are not restrictive of the various embodiments, as claimed.

Additional aspects and/or advantages will be set forth in part in the description which follows and, in part, will be apparent from the description, or may be learned by practice of the various embodiments.

### BRIEF DESCRIPTION OF THE DRAWINGS

FIG. 1 is an external perspective view of a notebook PC which is an embodiment of an electronic apparatus.

FIG. 2 is a perspective view of showing a bottom surface of the notebook PC shown in FIG. 1 in a closed state seen from a back side of FIG. 1.

FIG. 3 is a rear perspective view showing a bottom cover member from which a top cover member is removed.

FIG. 4 is a perspective view showing various components inside the bottom cover member from which the top cover member is removed in the same manner as in FIG. 3.

FIG. 5 is a perspective view showing a surface (a surface facing the top cover member) of the bottom cover member from which a circuit board is removed from a state shown in FIGS. 3 and 4.

FIG. 6 is a perspective view showing a surface (a surface facing the top cover member) of the circuit board removed from the bottom cover member.

FIG. 7 is a perspective view showing a state in which the bottom cover member is removed and the circuit board is mounted on the top cover member.

FIG. 8 is a perspective view of a surface of the circuit board facing the bottom cover member.

FIG. 9 is a view showing an inner surface of the top cover member.

FIG. 10 is a view showing an assembling procedure of a main body unit of the notebook PC.

FIG. 11 is a view showing the assembling procedure of the main body unit of the notebook PC.

FIG. 12 is a view showing a work procedure for replacing a fan.

FIG. 13 is a plan view of a state in which the circuit board is mounted on the bottom cover member.

FIG. 14 is a perspective view showing a cross-section taken along arrows X1-X1 in FIG. 13.

FIG. 15 is a cross-sectional view taken along arrows X1-X1 in FIG. 13.

FIG. 16 is an enlarged cross-sectional view of a portion of a circle R1 shown in FIG. 15.

FIG. 17 is an enlarged cross-sectional view of a portion of a circle R2 shown in FIG. 14.

FIG. 18 is an enlarged perspective view of a portion corresponding to the circle R1 or the circle R2 of the circuit board.

FIG. 19 is an enlarged perspective view of a portion corresponding to the circle R1 or the circle R2 of the bottom cover member.

FIG. 20 is an enlarged perspective view of a portion corresponding to the circle R1 or the circle R2 in a state in which the circuit board is mounted on the bottom cover member.

FIG. 21 is an enlarged cross-sectional view of a portion of a circle R3 shown in FIG. 15.

FIG. 22 is an enlarged cross-sectional perspective view of a portion of a circle R4 shown in FIG. 14.

FIG. 23 is a perspective view of a portion corresponding to the circle R3 or the circle R4 of the bottom cover member.

FIG. 24 is a perspective view of a portion corresponding to the circle R3 or the circle R4 in a state in which the circuit board is mounted on the bottom cover member.

FIG. 25 is a cross-sectional perspective view showing a cross-section taken along arrows X2-X2 in FIG. 13.

FIG. 26 is a cross-sectional view taken along arrows X2-X2 in FIG. 13.

FIG. 27 is an enlarged cross-sectional view of a portion of a circle R5 shown in FIG. 26.

FIG. 28 is an enlarged cross-sectional perspective view of a portion of a circle R6 shown in FIG. 25.

FIG. 29 is a view of a portion of the circle R5 or the circle R6 of the surface of the circuit board facing the bottom cover member.

FIG. 30 is an enlarged perspective view of a portion of the circle R5 or the circle R6 of the bottom cover member.

FIG. 31 is a plan view of a state in which the circuit board is mounted on the top cover member.

FIG. 32 is a cross-sectional view taken along arrows X3-X3 in FIG. 31.

FIG. 33 is an enlarged cross-sectional view of a portion of a circle R7 shown in FIG. 32.

FIG. 34 is an enlarged perspective view of a portion of the circle R7.

FIG. 35 is an enlarged cross-sectional view of a portion of a circle R8 shown in FIG. 32.

FIG. 36 is an enlarged perspective view of a portion of the circle R8.

FIG. 37 is an enlarged perspective view of a portion of a circle R9 shown in FIG. 31.

FIG. 38 is an enlarged perspective view of a portion of a circle R10 shown in FIG. 31.

FIG. 39 is an enlarged perspective view of a portion of a circle R11 shown in FIG. 31.

FIG. 40 is an enlarged perspective view of a portion of the circle R11 shown in FIG. 31 as seen from a direction different from that of FIG. 39.

### DETAILED DESCRIPTION OF THE EMBODIMENTS

Hereinafter, embodiments of the present invention will be described.

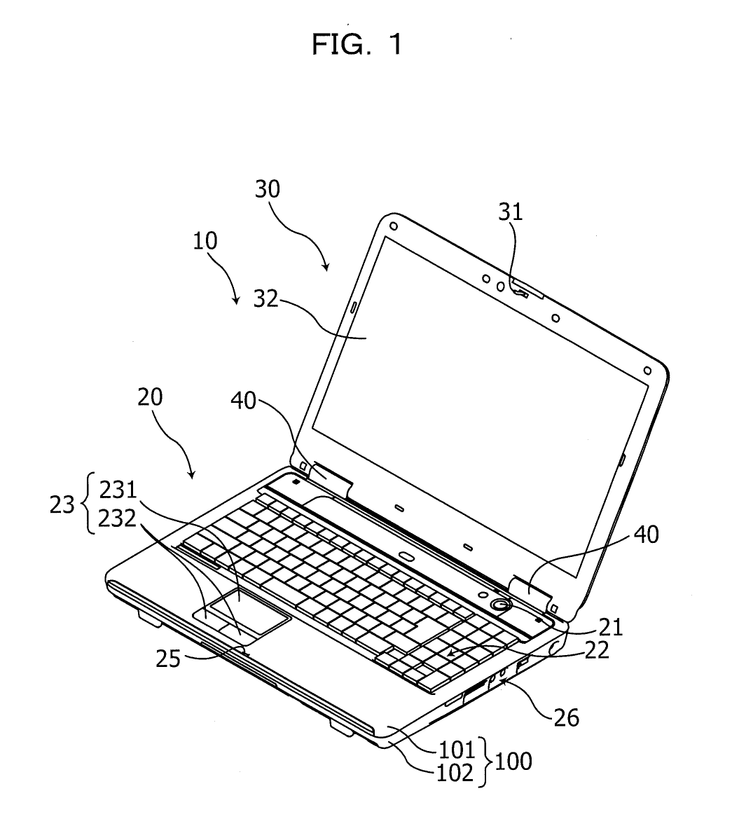

FIG. 1 is an external perspective view of a notebook type personal computer (hereinafter referred to “notebook PC) which is an embodiment of an electronic apparatus of the present invention.

A notebook PC 10 includes a main body unit 20 and a display unit 30. The main body unit 20 includes a housing 100 defining an outer shape thereof. The housing 100 includes two housing members, which are a top cover member 101 and a lower cover member 102 (also referred to as a bottom cover member). The main body unit 20 has an internal space enclosed by the top cover member 101 and the lower cover member 102. Various electronic components, such as a CPU (Central Processing Unit) and a circuit board on which a fan to cool the CPU and the like are mounted, are accommodated in the internal space. The main body unit 20 has a calculation function realized by the CPU and the like. The main body unit 20 includes a power button 21, a keyboard 22, and a pointing device 23, and the like on the surface thereof. The pointing device includes a touchpad 231 and left/right click buttons 232. The main body unit 20 also includes a lock hole 25 in the top surface thereof. A hook 31 provided on the display unit 30 enters the lock hole 25 and is locked in the lock hole 25, so that the display unit 10 is held in a closed state. The main body unit 20 includes various connectors 26 on both sides thereof.

The display unit 30 of the notebook PC 10 includes the above-mentioned hook 31, a display screen 32, and the like. The display unit 30 is supported by hinges 40 so that the display unit 30 can be opened and closed freely between an opened state in which the display screen 32 is opened as shown in FIG. 1 and a closed state in which the display unit 30 is closed on the main body unit 20 with the display screen 32 facing down.

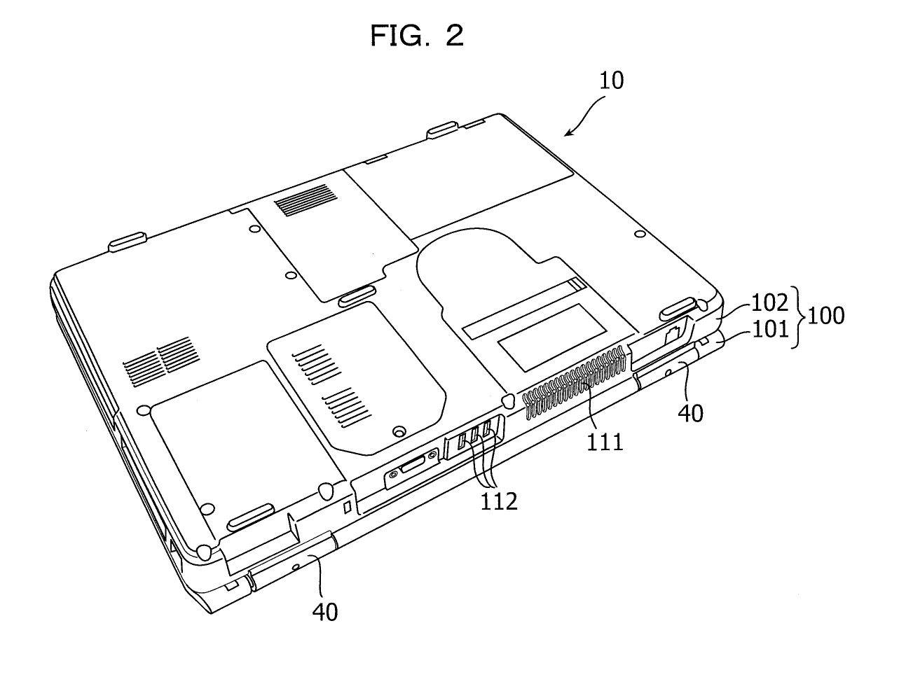

FIG. 2 is a perspective view showing the bottom surface of the notebook PC shown in FIG. 1 in the closed state seen from a back side (hinges 40 side) of FIG. 1.

The main body unit 20 includes an exhaust outlet 111 and three connector inlets 112 in the rear side surface. The exhaust outlet 111 is an outlet for blowing out air from a fan inside the main body unit 20 to the outside of the housing.

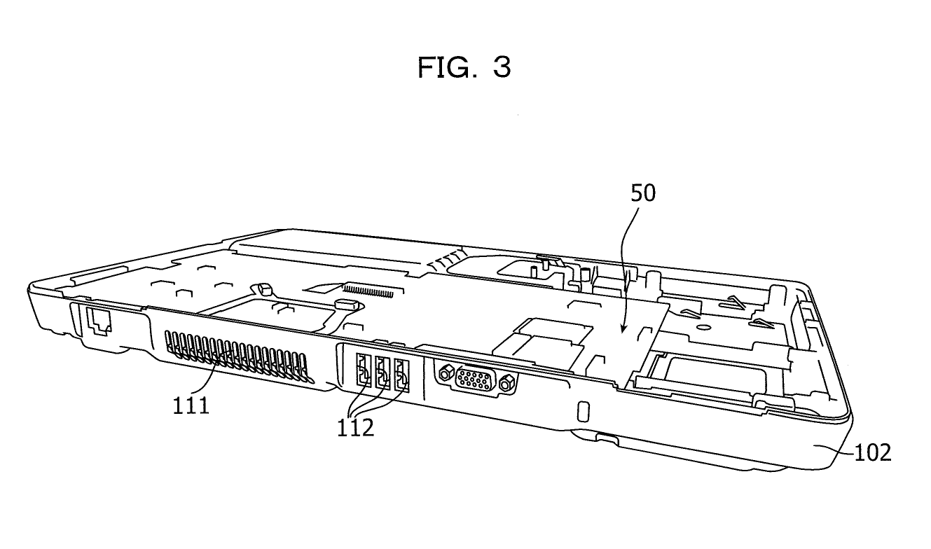

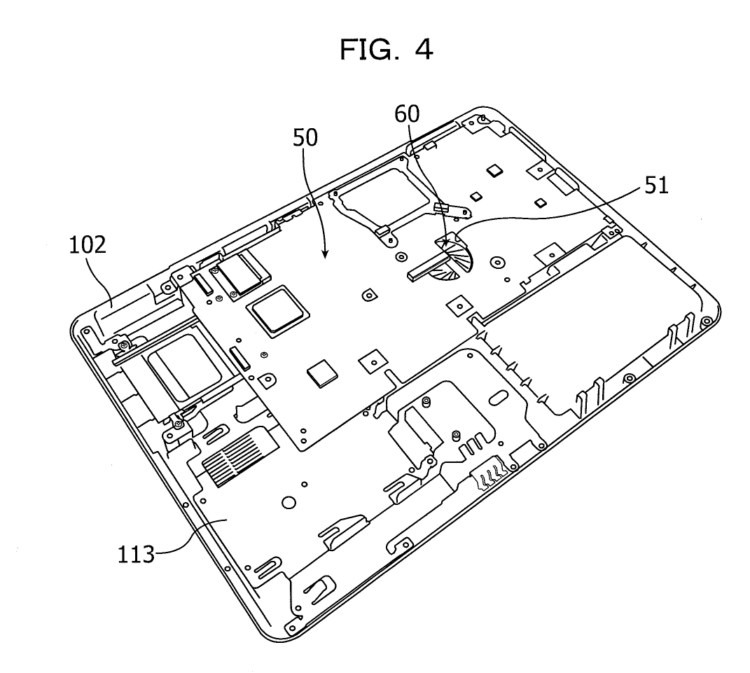

FIG. 3 is a rear perspective view showing the bottom cover member from which the top cover member is removed. FIG. 4 is a perspective view showing various components inside the bottom cover member from which the top cover member is removed in the same manner as in FIG. 3.

A circuit board 50 on which various electronic components are mounted is disposed at a portion near the exhaust outlet 111 inside the bottom cover member 102. The circuit board 50 includes an opening 51. As shown in FIG. 4, blades of a fan 60 mounted on a back surface of the surface shown in FIG. 4, in other words, mounted on a surface of the circuit board 50 facing the bottom cover member 102 are viewed from the opening 51. A shield plate 113 is fixed inside the bottom cover member 102.

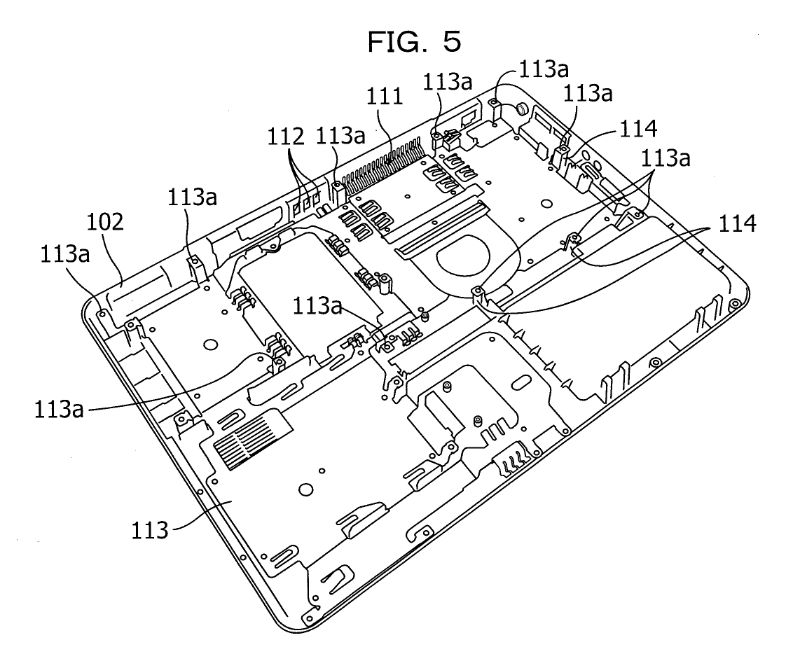

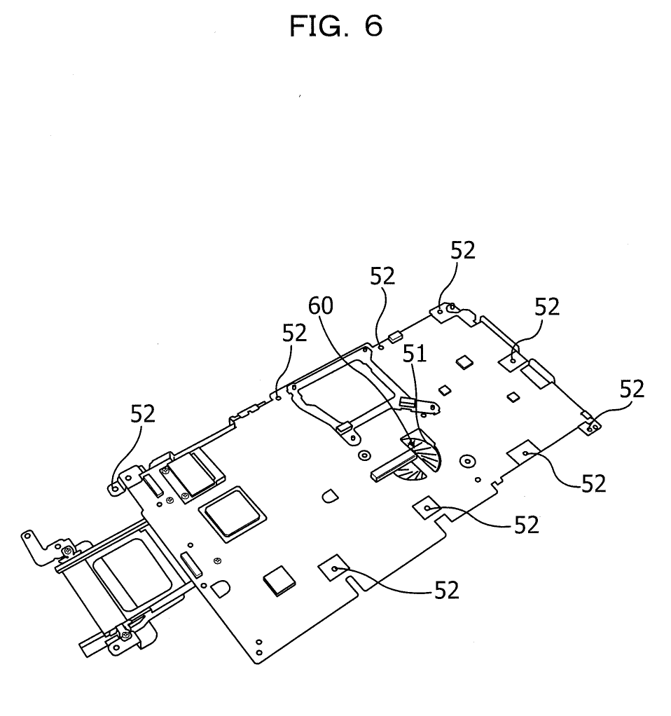

FIG. 5 is a perspective view showing the surface (the surface facing the top cover member) of the bottom cover member from which the circuit board 50 is removed from a state shown in FIGS. 3 and 4. FIG. 6 is a perspective view showing the surface (the surface facing the top cover member) of the circuit board removed from the bottom cover member.

The bottom cover member 102 includes a plurality of bosses 114 inside the bottom cover member 102. The bosses 114 and portions formed higher than the other portions inside the bottom cover member 102 have a through-hole for a screw clamp. Fixing portions 113a of the shield plate 113 are mounted on the portions where the through-hole for screw fixing is formed. The fixing portions 113a include a hole. The circuit board 50 and mounting brackets fixed to the circuit board 50 also include a screw fixing hole 52 passing through from the top surface to the bottom surface at a position corresponding to each boss 114 or the like. In a screw fixing operation, screws are inserted from the bottom surface of the bottom cover member 102, and the screws pass through the holes of the circuit board 50, and then the screws are fastened into screw holes (described below) formed in the top cover member 101. In this way, when the top cover member 101 is fixed to the bottom cover member 102 by the screws, the circuit board is also fixed by the screw. The circuit board 50 does not have portions individually fixed to the bottom cover member 102 or the top cover member 101 by screws, and only has a structure to be tightened together with the bottom cover member 102 and the top cover member 101 when the bottom cover member 102 and the top cover member 101 are fixed together by screws. Before the screw fixing operation, the position of the circuit board 50 needs to be precisely controlled. The position control structure will be described below.

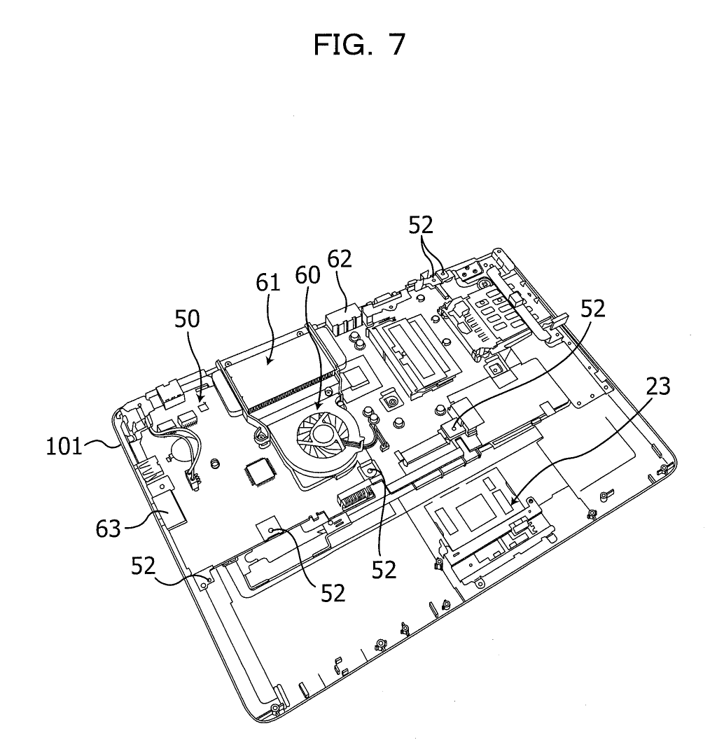

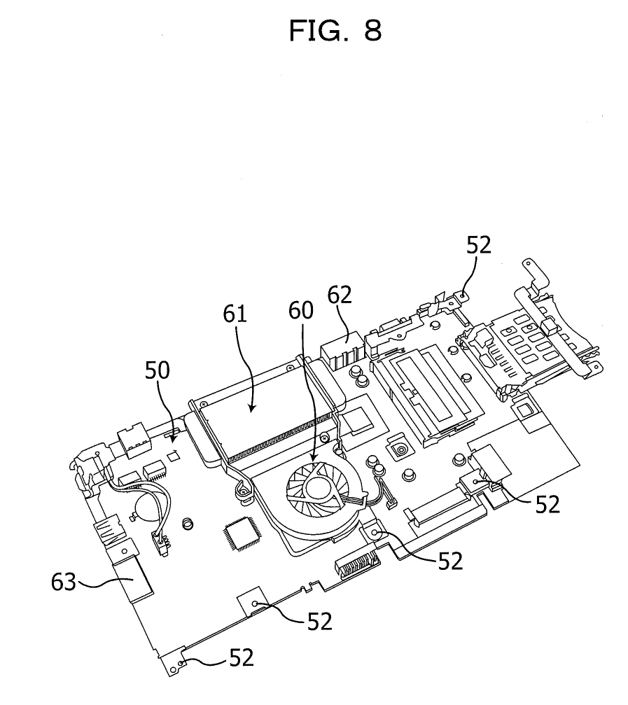

FIG. 7 is a perspective view showing a state in which the bottom cover member is removed and the circuit board is mounted on the top cover member. FIG. 8 is a perspective view of a surface of the circuit board facing the bottom cover member.

As shown in FIG. 7, the circuit board 50 and the pointing device 23 are arranged on the top cover member 101. FIG. 7 shows the back surface (the surface facing the bottom cover member) of the circuit board 50. FIG. 7 shows the back surface of the pointing device 23 whose outer surface is shown in FIG. 1.

The fan 60, a heatsink 61 disposed on the side of the exhaust outlet 111 (refer to FIGS. 2 and 3) of the fan 60, a plurality of connectors 62 and 63, and other components are mounted on the surface of the circuit board 50 facing the bottom cover member. The CPU (not shown in the figures) is mounted on the circuit board 50 at a position immediately below the heatsink 61. When the CPU is running, the CPU generates a considerable amount of heat. Therefore, a cooling structure is employed in which the heat generated from the CPU is absorbed by the heatsink, the heatsink is cooled by air blown from the fan 60, and the air is exhausted from the exhaust outlet to the outside of the housing. In the same manner as in FIG. 6, the screw fixing holes 52 used to tighten the circuit board 50 together with the bottom cover member 102 and the top cover member 101 appear in the circuit board 50 shown in FIGS. 7 and 8.

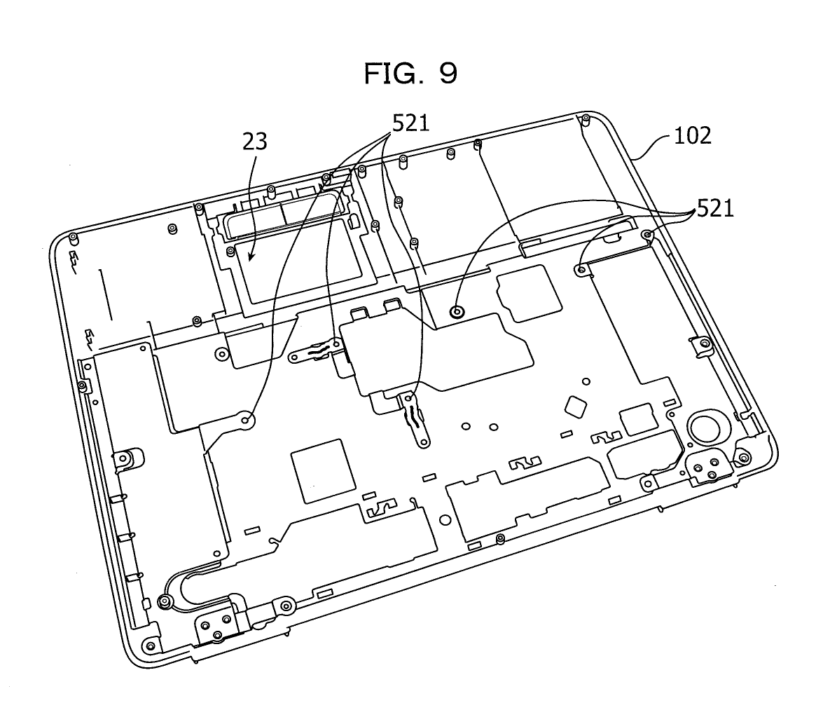

FIG. 9 is a view showing an inner surface of the top cover member.

Inside the top cover member 101, screw holes 521 are formed at each position corresponding to the screw fixing holes of the bottom cover member 102 and the screw fixing holes 52 of the circuit board 50. Screws inserted from the bottom surface of the bottom cover member 102 pass through the circuit board 50, and are fastened into the screw holes 521 formed in the inner surface of the top cover member 101. As described above, the circuit board 50 is tightened together with the top cover member 101 and the bottom cover member 102. However, the circuit board 50 is not individually fixed to the bottom cover member 102 or individually fixed to the top cover member 101 by screws. Therefore, the circuit board 50 can be taken out from either a state in which the top cover member is removed as shown in FIG. 4 or a state in which the bottom cover member is removed as shown in FIG. 7.

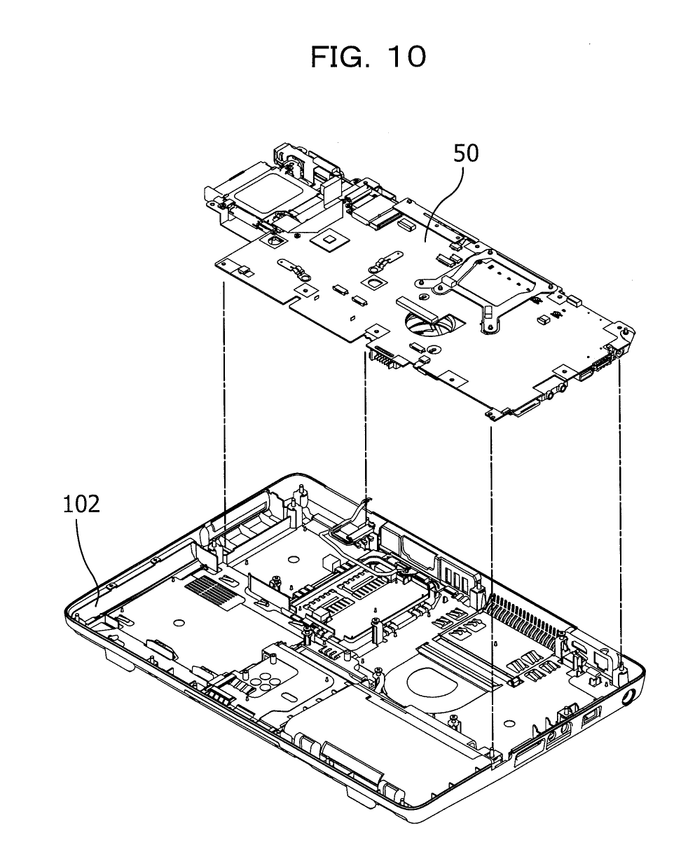

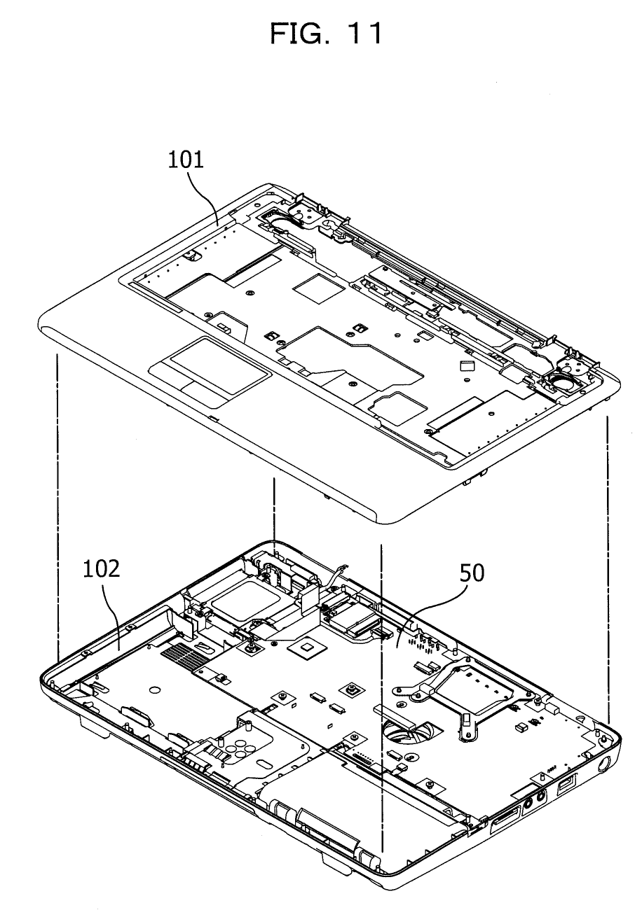

FIGS. 10 and 11 are views showing an assembling procedure of the main body unit of the notebook PC.

When assembling the main body unit, first, as shown in FIG. 10, the circuit board 50 is placed inside the bottom cover member 102. Next, as shown in FIG. 11, the top cover member 101 is placed on the bottom cover member 102 on which the circuit board 50 is placed. Then, as described above, screws are inserted from the bottom surface of the bottom cover member 102 and the screws are fastened.

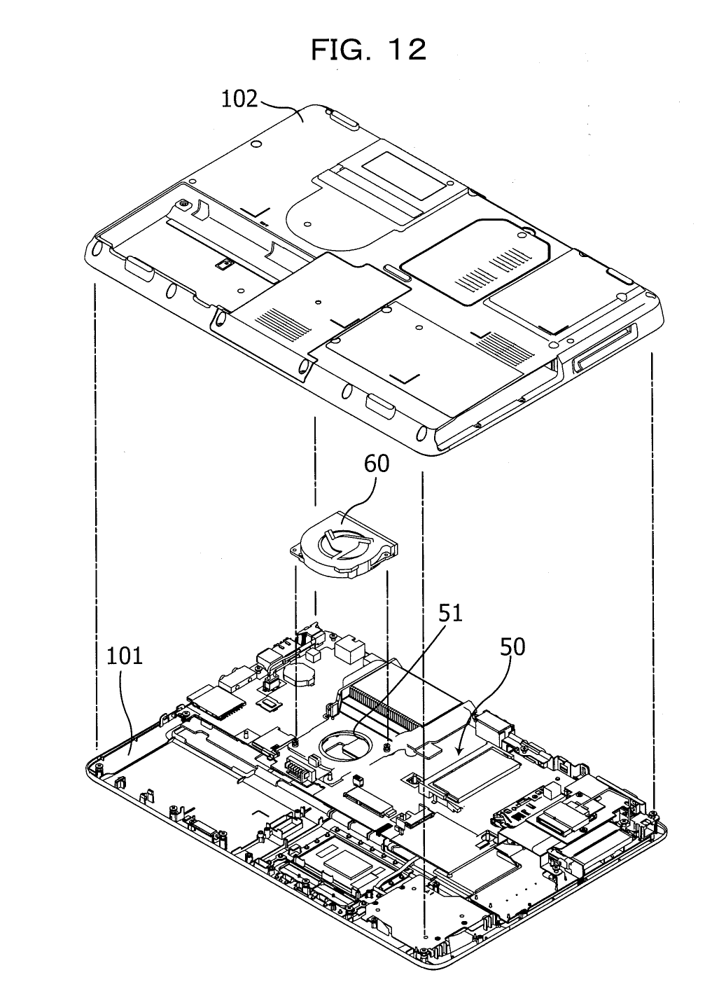

FIG. 12 is a view showing a work procedure for replacing the fan.

The fan 60 has a mechanical movable portion, so that the life of the fan 60 is shorter than that of other components, and thus the fan 60 may often be replaced.

In the notebook PC, the fan 60 is mounted on the surface of the circuit board 50 facing the bottom cover member.

When replacing the fan, first, the bottom cover member 102 is set to face upward, and the screws fixing the bottom cover member 102 are removed. Thereafter, as shown in FIG. 12, the bottom cover member 102 is removed, and in this state, the fan 60 is removed and replaced by a new fan 60. If necessary, in this state, the circuit board 50 can be removed.

In the above description with reference to FIGS. 10 and 11, the assembling procedure for assembling the components sequentially from the bottom cover member 102 is described. However, as shown in FIG. 12, it is also possible to assemble the main body unit by a procedure in which, first, the top cover member 101 is put down, next, the circuit board 50 is placed on the top cover member 101, and further the bottom cover member 102 is placed on the circuit board 50 and fixed with screws.

Next, the position control structure of the circuit board will be described.

In the main body unit 20 of the notebook PC 10, the position control structure of the circuit board 50 is included in both the bottom cover member 102 and the top cover member 101. However, when a structure for precisely controlling the position of the circuit board 50 is included in both the bottom cover member 102 and the top cover member 101, the, position control structures of both members may interfere with each other due to manufacturing dimensional variation or the like of the bottom cover member 102 and the top cover member 101. Because of this, the position control of the circuit board may be impossible. Therefore, in this embodiment, the bottom cover member 102 has a position control structure for precisely controlling the position of the circuit board 50, and the top cover member 101 has a position control structure for controlling the position of the circuit board 50 less precisely than the bottom cover member 102.

As described above with reference to FIG. 12, the circuit board 50 is placed on the top cover member 101, and then the bottom cover member 102 may be placed over the circuit board 50. Therefore, the bottom cover member 102 includes a guiding structure for guiding the circuit board 50 that is roughly positioned on the top cover member 101 into a precisely controlled position. When, instead of the top cover member 101, the bottom cover member 102 has a structure for precisely controlling the position, the advantages described below appear. The connectors 62, 63, and the like are mounted on the circuit board 50. The bottom cover member 102 has openings to which connectors connected to the connectors 62, 63, and the like of the circuit board 50 are inserted. Even when the top cover member 101 is removed from a state in which the bottom cover member 102 is placed under the top cover member 101 (a normal setting state of the notebook PC) and a connecter needs to be inserted from outside while the circuit board 50 is placed on the bottom cover member 102, the connector from the outside can be correctly inserted into a connector on the circuit board 50 through an opening of the bottom cover member 102 because the bottom cover member 102 has a structure for precisely controlling the position.

Hereinafter, first, the position control structure of the bottom cover member 102 will be described. Thereafter, the position control structure of the top cover member 101 will be described.

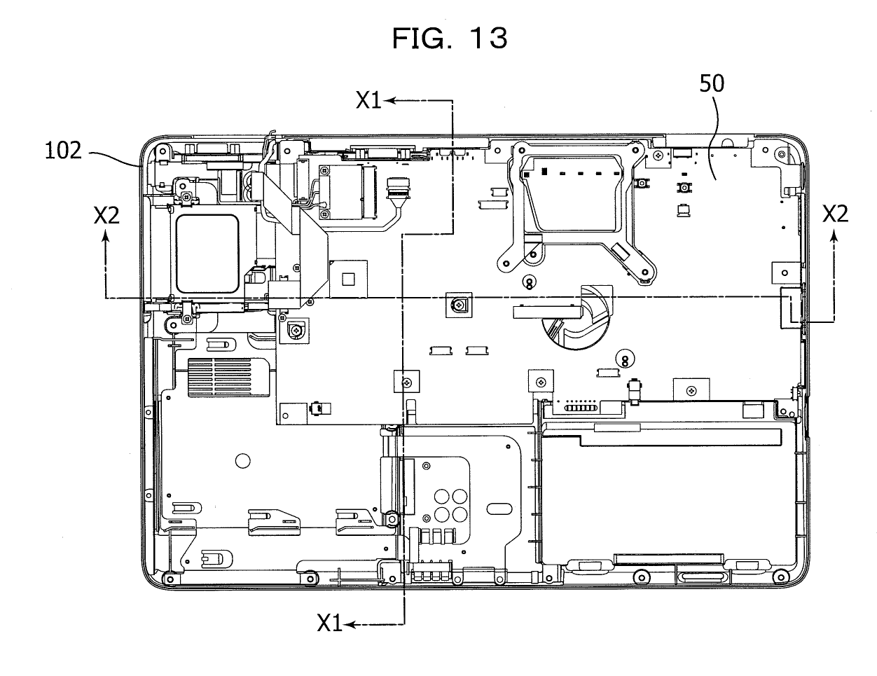

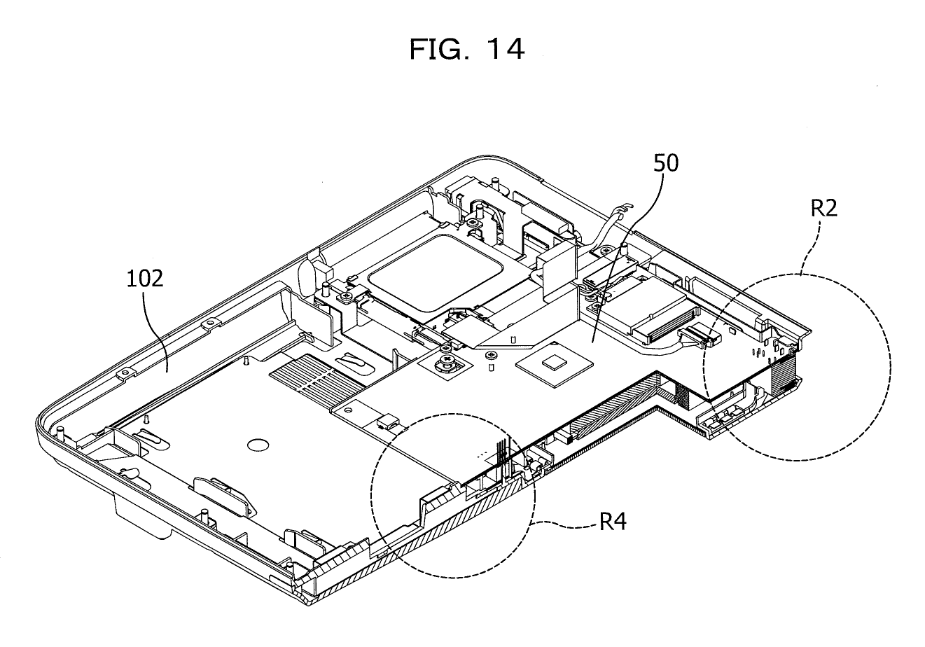

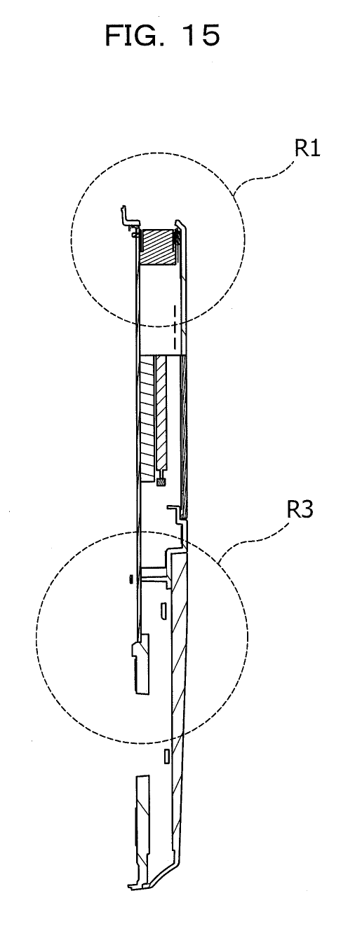

FIG. 13 is a plan view of a state in which the circuit board is mounted on the bottom cover member. FIG. 14 is a perspective view showing a cross-section taken along arrows X1-X1 in FIG. 13. FIG. 15 is a cross-sectional view taken along arrows X1-X1 in FIG. 13.

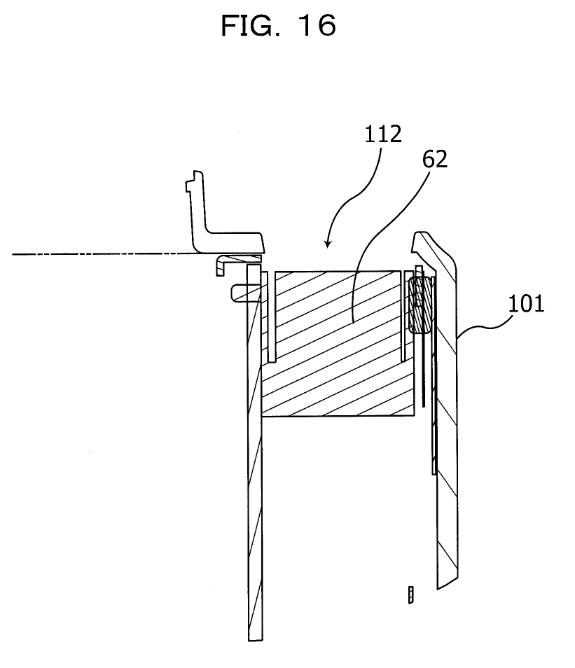

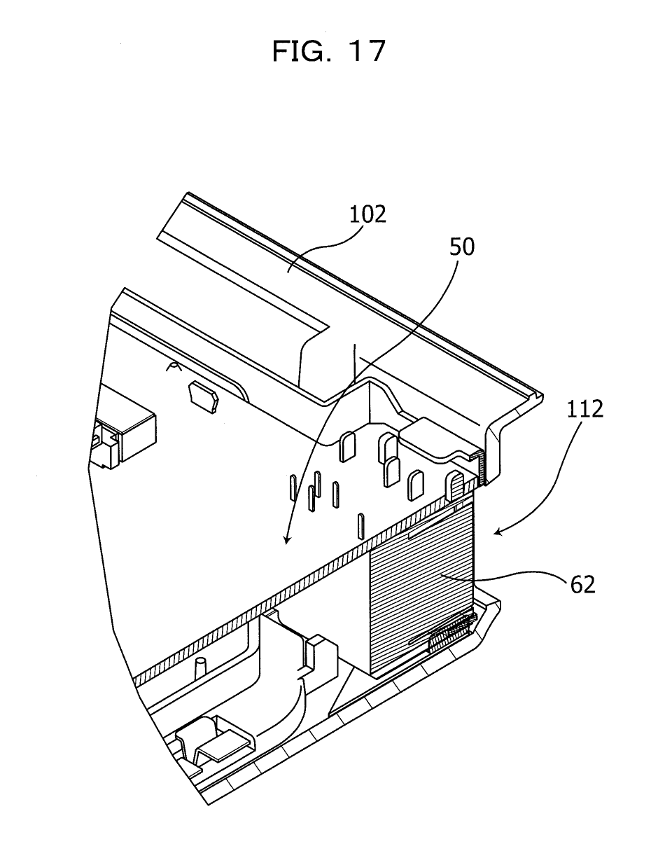

FIG. 16 is an enlarged cross-sectional view of a portion of a circle R1 shown in FIG. 15. FIG. 17 is an enlarged cross-sectional view of a portion of a circle R2 shown in FIG. 14. The circle R1 and the circle R2 show the same portion.

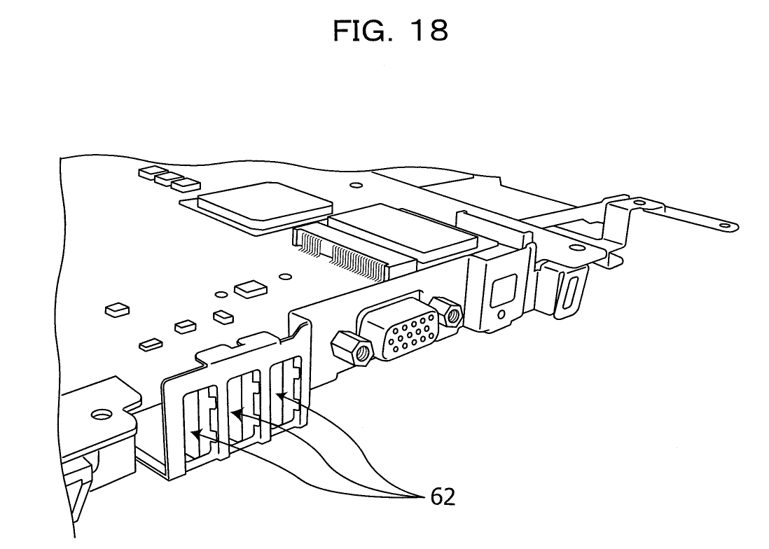

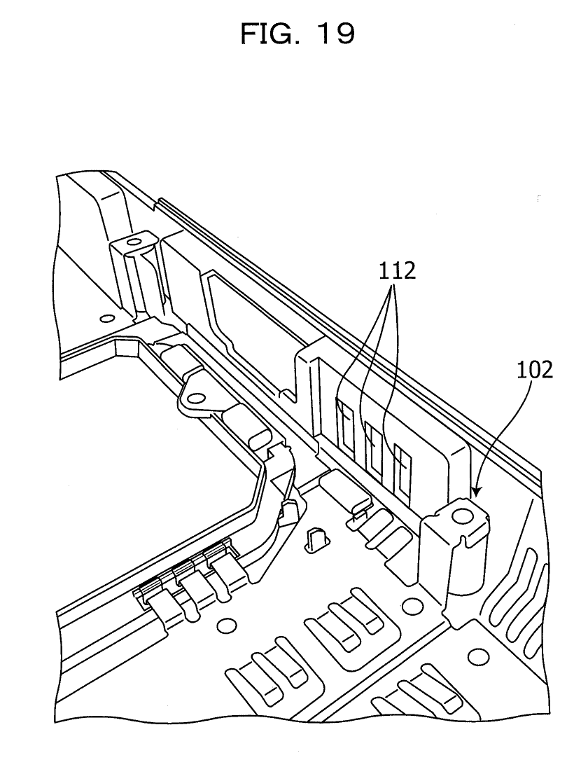

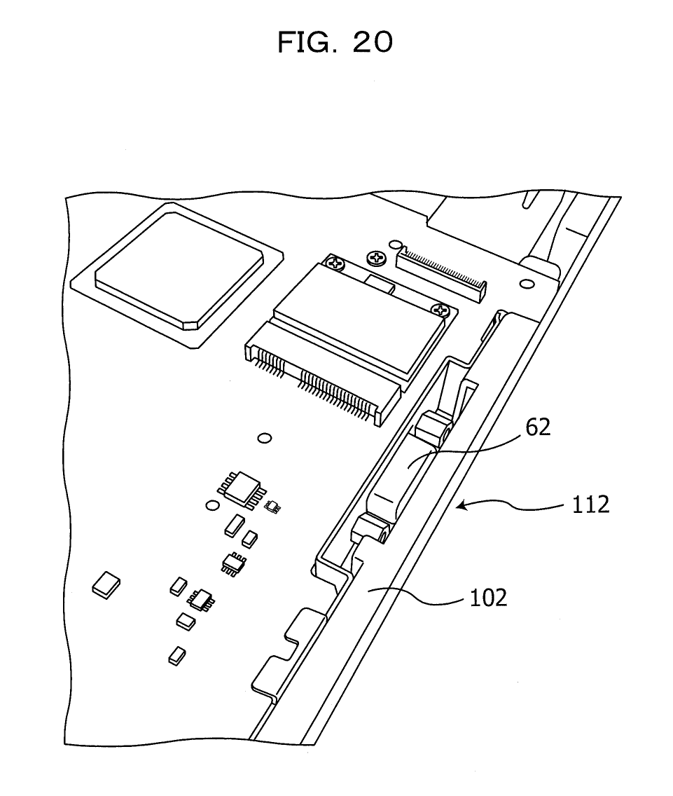

FIG. 18 is an enlarged perspective view of a portion corresponding to the circle R1 or the circle R2 of the circuit board. FIG. 19 is an enlarged perspective view of a portion corresponding to the circle R1 or the circle R2 of the bottom cover member. FIG. 20 is an enlarged perspective view of a portion corresponding to the circle R1 or the circle R2 in a state in which the circuit board is mounted on the bottom cover member.

The circuit board has the connector 62 shown in FIG. 18 (also refer to FIG. 7) at a position viewed from the openings 112 shown in FIG. 19 (also refer to FIG. 2).

When a bracket that supports the connector 62 comes into contact with a wall of the bottom cover member 102 at which the openings 112 are formed, first, the position of the bracket is controlled.

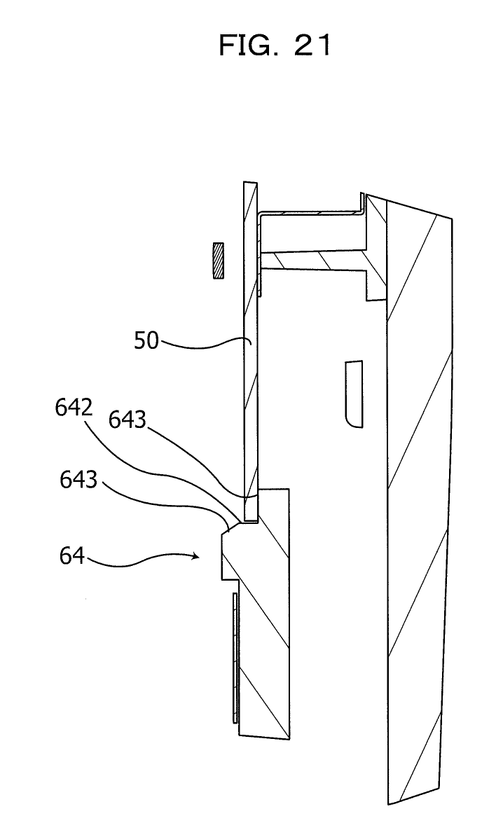

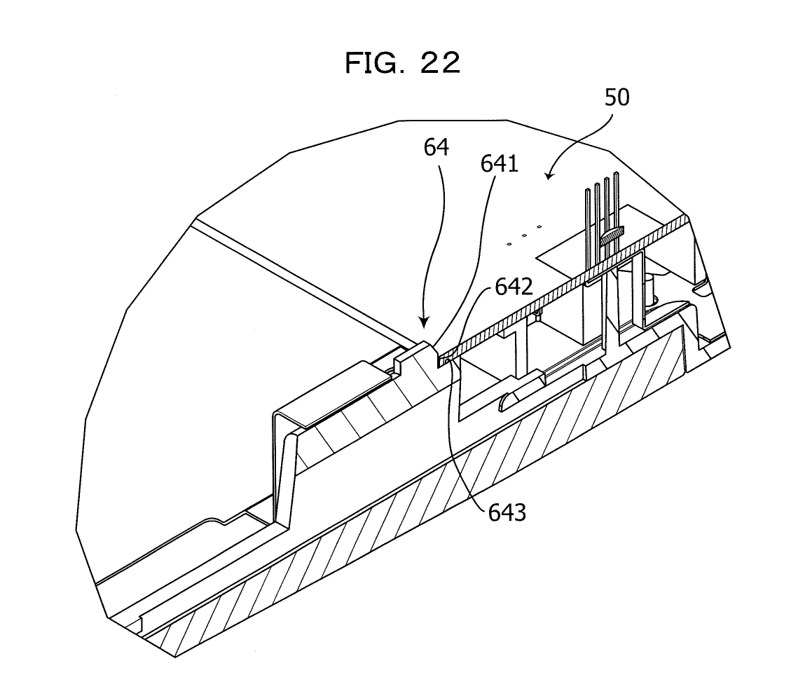

FIG. 21 is an enlarged cross-sectional view of a portion of a circle R3 shown in FIG. 15. FIG. 22 is an enlarged cross-sectional perspective view of a portion of a circle R4 shown in FIG. 14. The circle R3 and the circle R4 show the same portion.

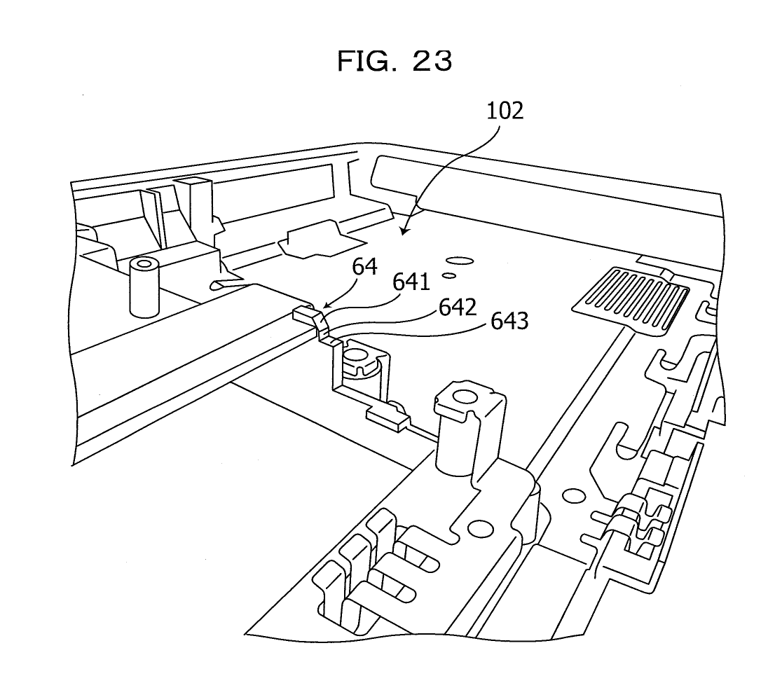

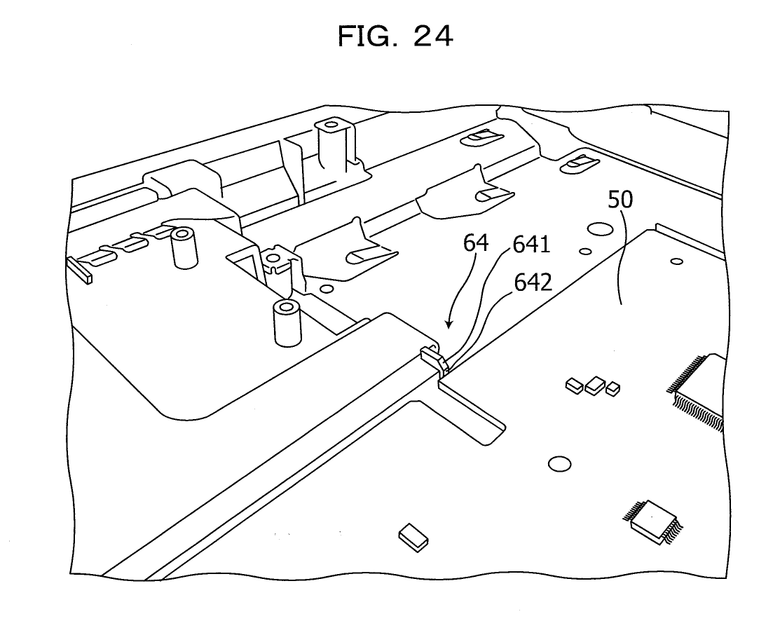

FIG. 23 is a perspective view of a portion corresponding to the circle R3 or the circle R4 of the bottom cover member. FIG. 24 is a perspective view of a portion corresponding to the circle R3 or the circle R4 in a state in which the circuit board is mounted on the bottom cover member.

As shown in FIG. 24, the bottom cover member 102 has a rib 64 formed upright on the inner surface thereof. The rib 64 includes a guide slope 641 which forms a part of a guide section defined in the present invention, and following the guide slope 641, the rib 64 includes a position control standing wall 642 which controls the position of the circuit board 50. The rib 64 further includes a support platform 643 that supports the circuit board 50.

When the circuit board is placed on the bottom cover member 102, the circuit board 50 is guided by the guide slope 641 to be mounted on the support platform 643, and a side edge of the circuit board 50 comes into contact with the position control standing wall 642. At this time, the bracket that supports the connector 62 described above with reference to FIGS. 16 to 20 comes into contact with the wall in which the openings 112 are formed. Based on this, the position of the circuit board 50 is controlled in the horizontal direction in FIG. 13 with respect to the bottom cover member 102 (the depth direction in FIG. 1).

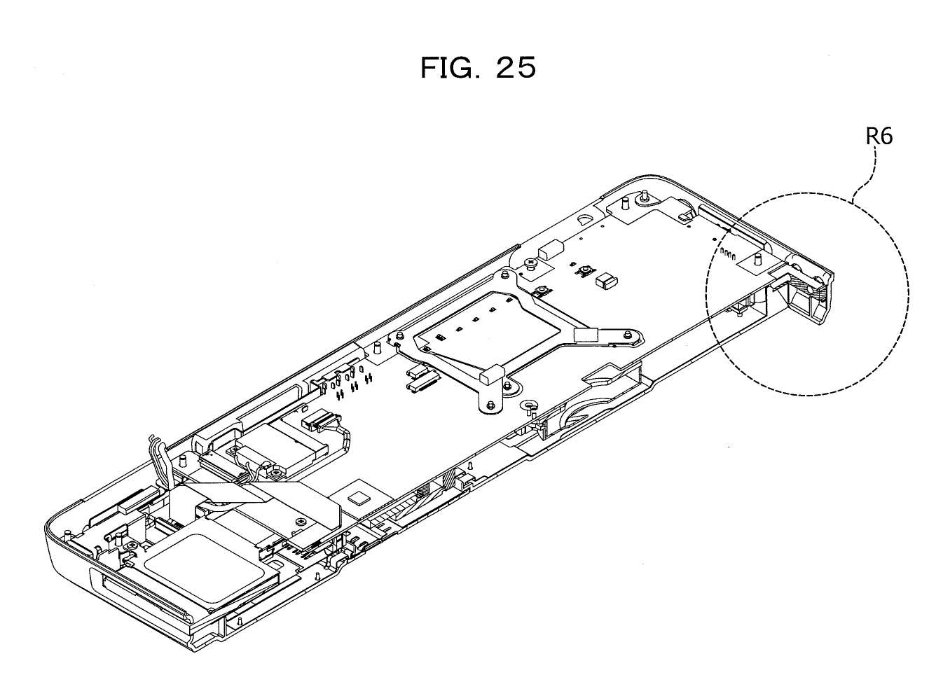

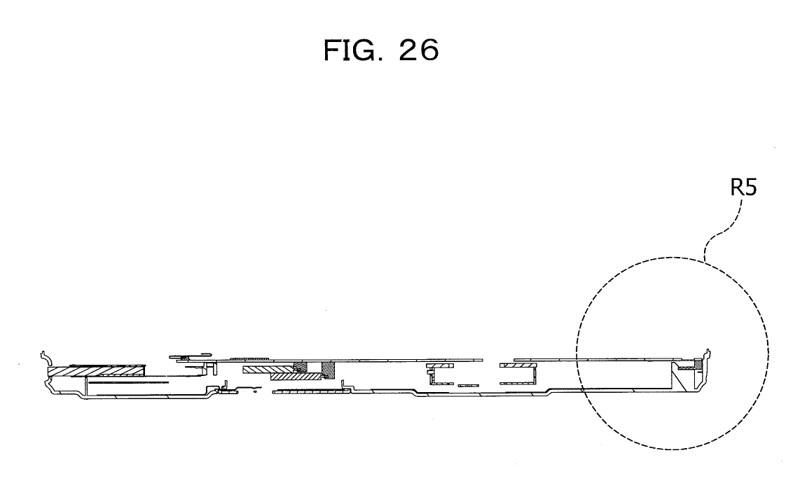

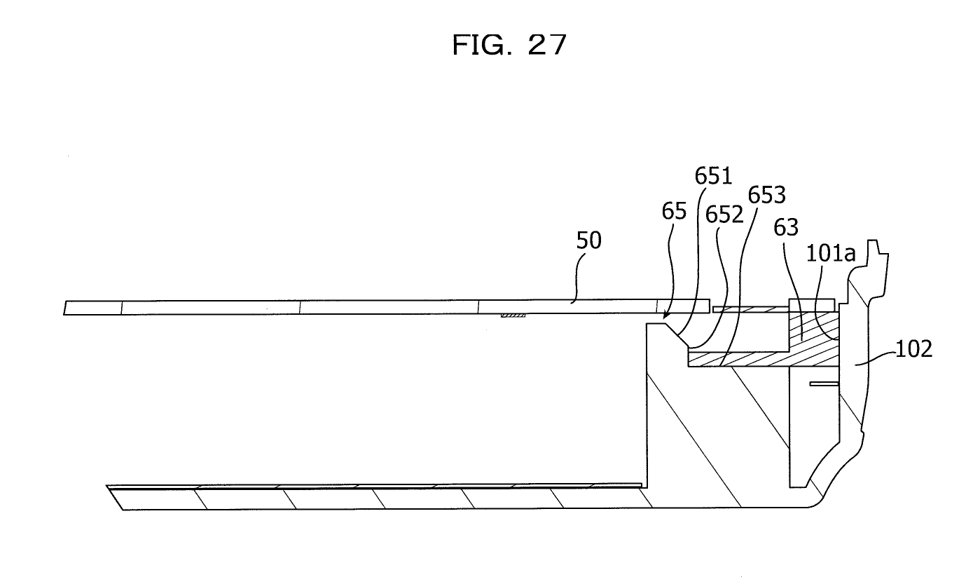

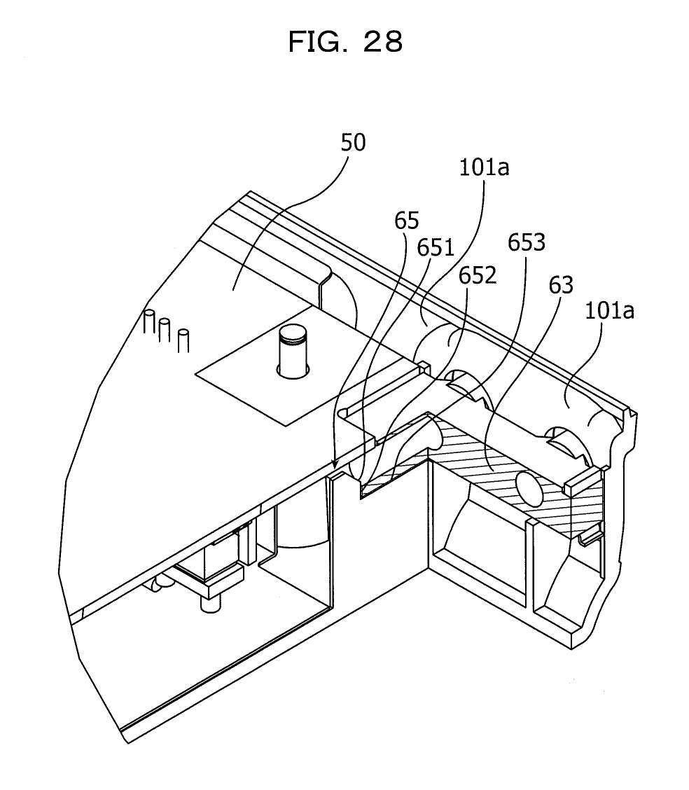

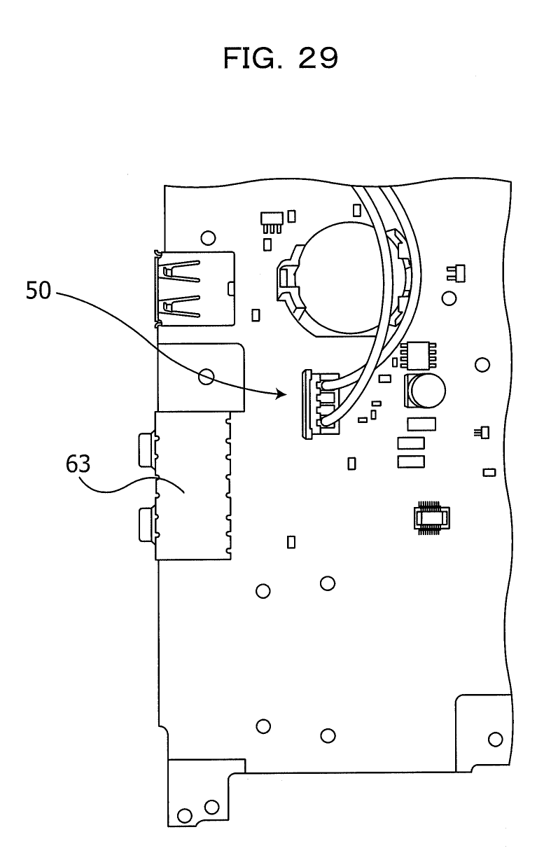

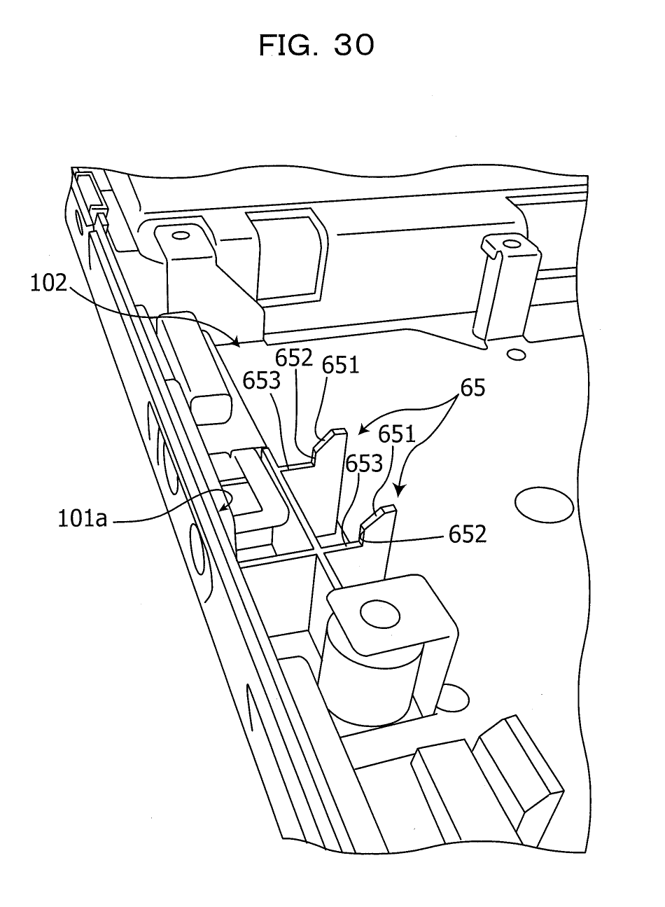

FIG. 25 is a cross-sectional perspective view showing a cross-section taken along arrows X2-X2 in FIG. 13. FIG. 26 is a cross-sectional view taken along arrows X2-X2 in FIG. 13. FIG. 27 is an enlarged cross-sectional view of a portion of a circle R5 shown in FIG. 26. FIG. 28 is an enlarged cross-sectional perspective view of a portion of a circle R6 shown in FIG. 25. FIG. 29 is a view of a portion of the circle R5 or the circle R6 of the surface of the circuit board facing the bottom cover member. FIG. 30 is an enlarged perspective view of a portion of the circle R5 or the circle R6 of the bottom cover member.

As shown in FIG. 29 (also refer to FIG. 8), the circuit board 50 has the connector 63 on the surface thereof facing the bottom cover member. As shown in FIG. 30, the bottom cover member 102 has a rib 65 formed upright on the inner surface thereof. The rib 65 includes a guide slope 651 which forms a guide section defined in the present invention, and following the guide slope 651, the rib 65 includes a position control standing wall 652 which controls the position of the connector 63. The rib 65 further includes a support platform 653 that supports the connector 63.

When the circuit board 50 is placed on the bottom cover member 102, the connector 63 mounted on the circuit board 50 is guided by the guide slope 651 to be mounted on the support platform 653. At this time, the connector 63 is sandwiched between the position control standing wall 652 and an inner surface 101a of the side wall of the bottom cover member 102. Based on this, the position of the connector 63, in other words, the position of the circuit board 50 on which the connector 63 is mounted is controlled in the left-right direction.

Next, the position control structure of the circuit board 50 by the top cover member 101 will be described.

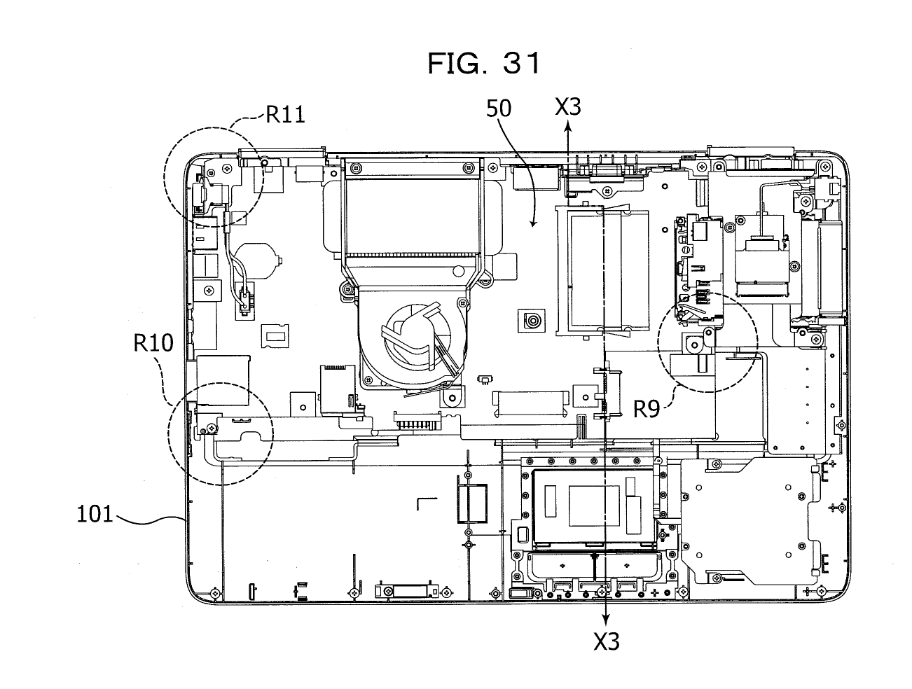

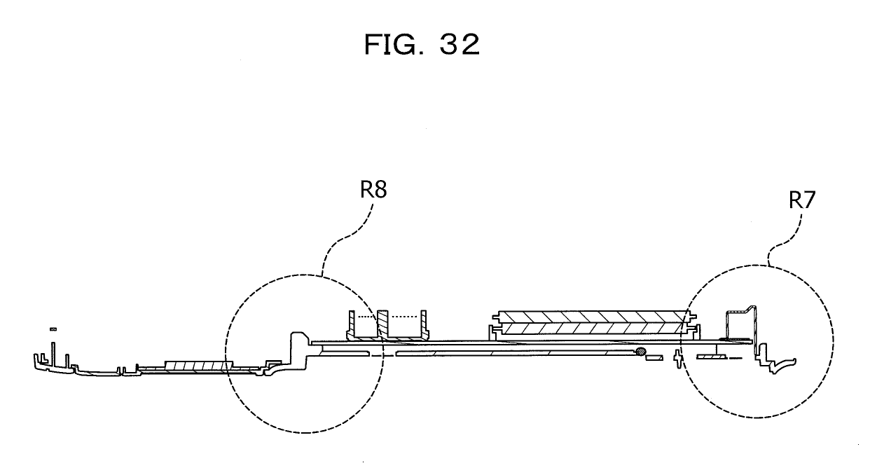

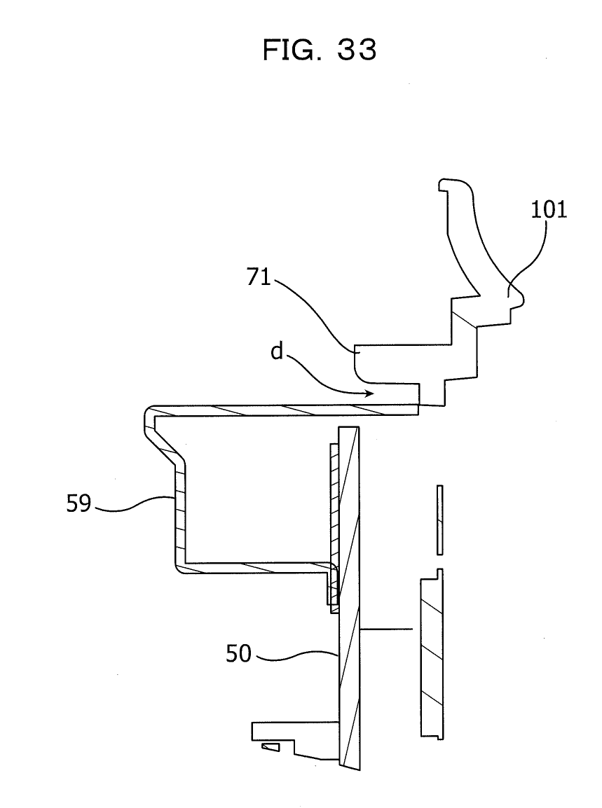

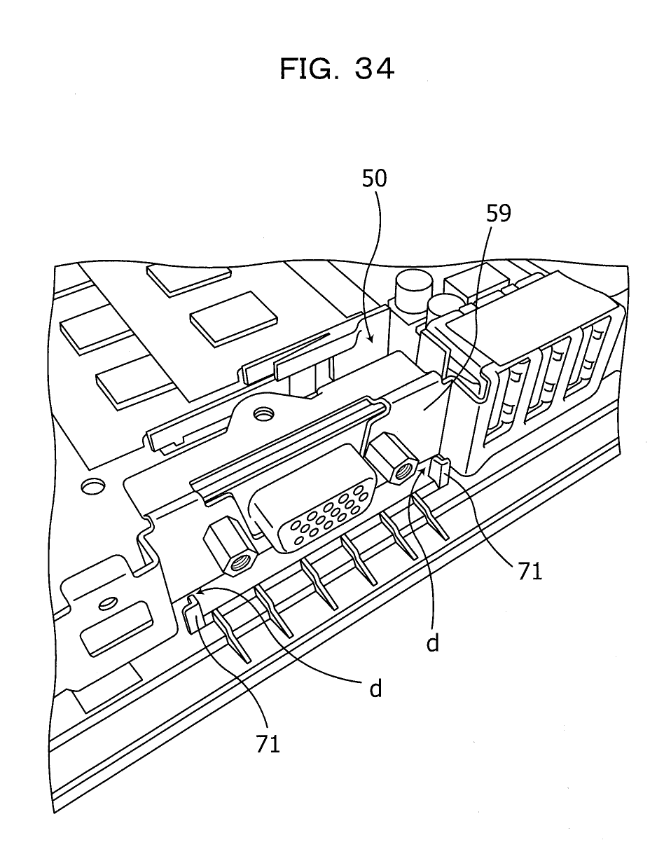

FIG. 31 is a plan view of a state in which the circuit board is mounted on the top cover member. FIG. 32 is a cross-sectional view taken along arrows X3-X3 in FIG. 31. FIG. 33 is an enlarged cross-sectional view of a portion of a circle R7 shown in FIG. 32. FIG. 34 is an enlarged perspective view of a portion of the circle R7.

The top cover member 101 includes a rib 71 formed upright on the inner surface thereof. The rib 71 performs a part of the position control of the circuit board 50. A reinforcement bracket 59 that reinforces the connector mounted on the circuit board 50 faces the rib 71. There is a space of a gap d between the rib 71 and the reinforcement bracket 59.

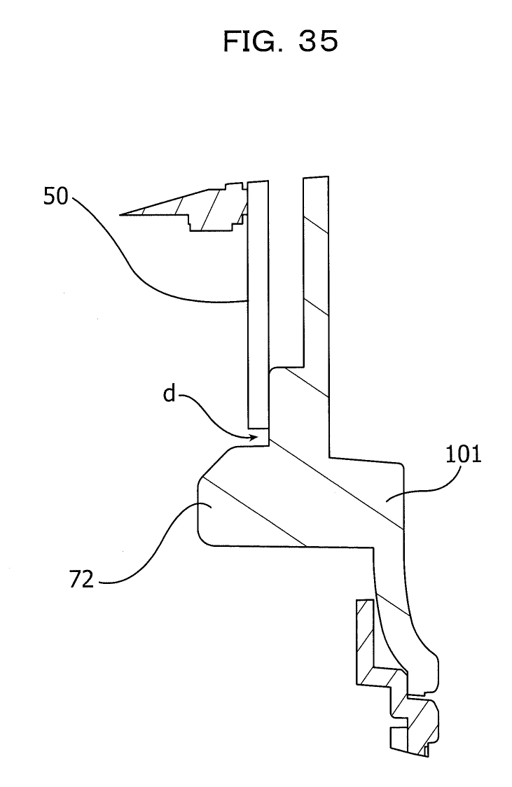

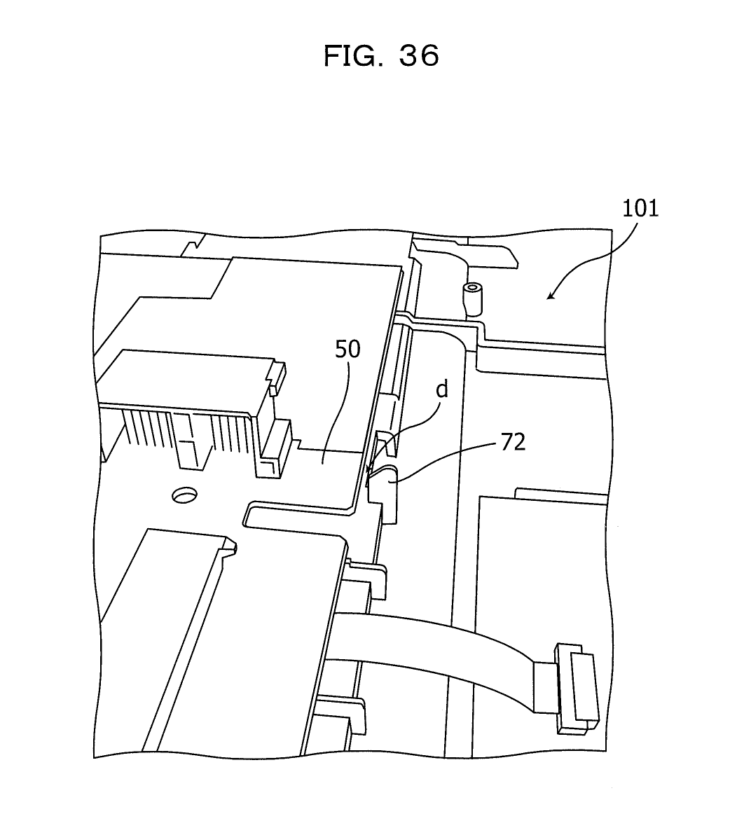

FIG. 35 is an enlarged cross-sectional view of a portion of a circle R8 shown in FIG. 32. FIG. 36 is an enlarged perspective view of a portion of the circle R8.

As shown in FIGS. 35 and 36, a rib 72 is formed on the inner wall surface of the top cover member 101. A dimensional allowance d is provided between the rib 72 and a side edge of the circuit board 50.

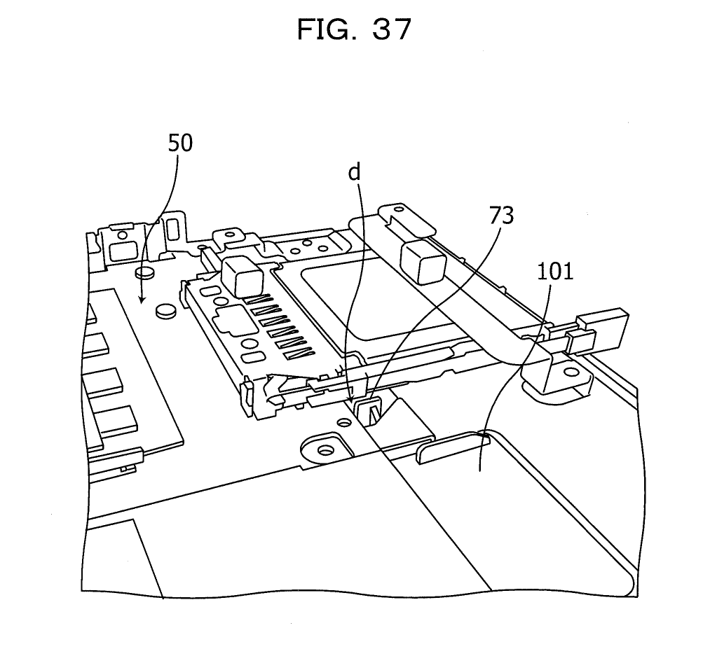

FIG. 37 is an enlarged perspective view of a portion of a circle R9 shown in FIG. 31.

As shown in FIG. 37, the top cover member 101 also has a rib 73 in this portion. A gap is formed between the rib 73 and the circuit board 50.

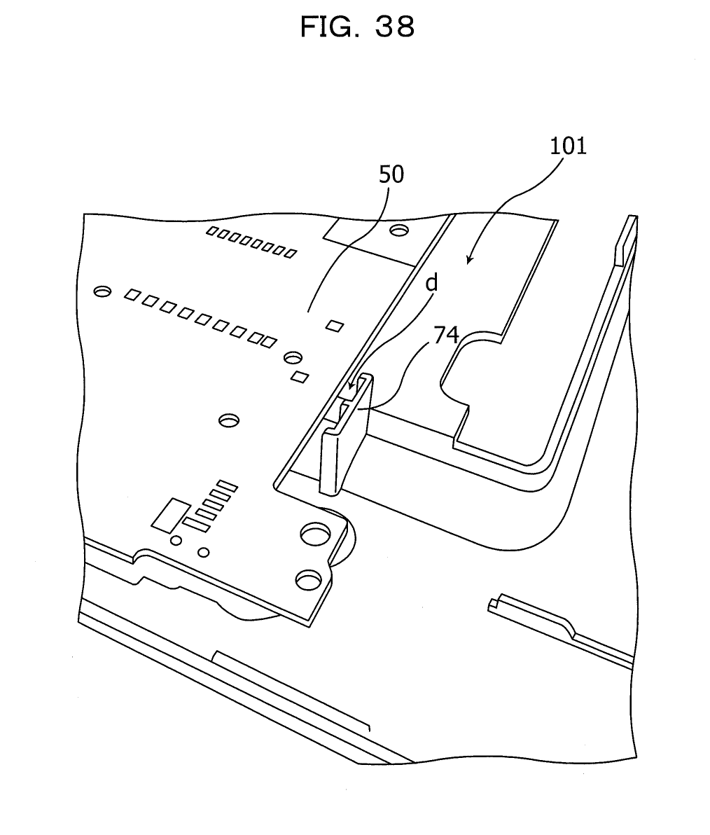

FIG. 38 is an enlarged perspective view of a portion of a circle R10 shown in FIG. 31.

As shown in FIG. 38, the top cover member 101 has a rib 74 also in this portion. A gap is formed between the rib 74 and the circuit board 50.

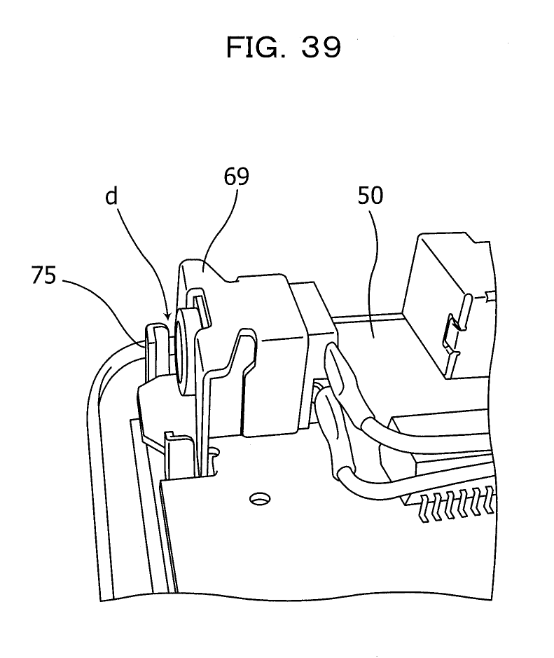

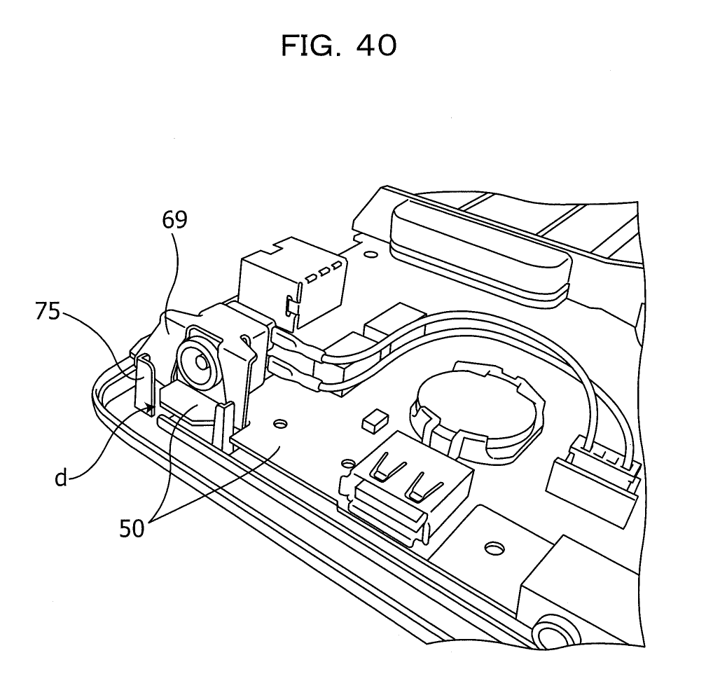

FIG. 39 is an enlarged perspective view of a portion of a circle R11 shown in FIG. 31. FIG. 40 is an enlarged perspective view of a portion of the circle R11 shown in FIG. 31 as seen from a direction different from that of FIG. 39.

As shown in FIGS. 39 and 40, the top cover member 101 has a rib 75 also in this portion. As shown in FIG. 39, a gap d is formed between a support bracket 69 that supports a connector mounted on the circuit board 50 and the rib 75 in the left-right direction. As shown in FIG. 40, a gap d is formed between the rib 75 and the circuit board 50 in the depth direction in the state of FIG. 1.

In this way, the position of the circuit board 50 placed on the top cover member 101 is roughly controlled by the ribs 71 to 75 of the top cover member 101 and the like in both the depth direction and the left-right direction. In this state, when the bottom cover member 102 is placed on the top cover member 101, the circuit board 50 is guided by the guide slope 641 (FIG. 23) and the guide slope 651 (FIG. 30) described above to a position precisely controlled by the bottom cover member 102.

In this way, in this embodiment, the position of the circuit board 50 is precisely controlled by only the bottom cover member 102 between the top cover member 101 and the bottom cover member 102, so that even when a dimensional error occurs during manufacturing, it is possible to avoid interference between the position control structures of the bottom cover member 102 and the top cover member 101 for the circuit board 50.

In addition, even when the circuit board 50 is placed on the top cover member 101 and the position of the circuit board 50 is roughly controlled, the position of the circuit board 50 is precisely controlled in the main body unit 20 when the bottom cover member 102 is placed on the top cover member 101. Based on this, a smooth screw fixing operation is realized.

Although a notebook PC is described as the embodiment, the present invention need not be a notebook PC, and the present invention can be applied to general electronic apparatuses. Although an example is described in which a fan is used as a component to be replaced, the component to be replaced is not limited to a fan, but the component to be replaced may be any component mounted on the circuit board.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An electronic apparatus, comprising:
a substrate that includes a component;
a first cover member that includes a first position control section that controls a position of the substrate; and
a second cover member that forms an internal space in cooperation with the first cover member and includes a second position control section that controls the position of the substrate,
wherein when the substrate is supported by either one of the first cover member and the second cover member, the substrate is not fixed to the one of the cover members, and when the first cover member and the second cover member are fastened together, the substrate is fixed in the internal space.

2. The electronic apparatus according to claim 1, wherein
the second position control section includes a guide section configured to guide the substrate by the first position control section to a position-controlled position with respect to the first cover member.

3. The electronic apparatus according to claim 1, wherein
the substrate includes through-holes passing through a top surface and a bottom surface of the substrate, the substrate includes no fixing portion fixed to only one of the first cover member and the second cover member, and the substrate is fastened together with both the first cover member and the second cover member by screw members passing through the through-holes.

4. The electronic apparatus according to claim 1, wherein
the second cover member has openings into which connectors are inserted from outside the electronic apparatus, and
the substrate includes a connector that is connected to the connectors inserted from the openings and mounted at a position facing an internal surface of the openings.

5. The electronic apparatus according to claim 1, wherein
the component is a fan that is mounted on one of a top surface and a bottom surface of the substrate and forms an air flow in the internal space.

6. The electronic apparatus according to claim 1, further comprising:
a display unit that includes a display screen; and
a main body unit that has a calculation function and supports the display unit so that the display unit is openable and closable,
wherein the main body unit includes a top cover as the first cover member that covers a top side and a bottom cover as the second cover member that covers a bottom side.
